(19) United States
(12) Patent Application Publication
(10) Pub. No.: US 2002/0064894 A1
(43) Pub. Date: May 30, 2002

(54) Buried transistor for a liquid crystal display system

(76) Inventor: Chiu-Te Lee, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/858,510

(22) Filed: May 17, 2001

Related U.S. Application Data
(62) Division of application No. 09/725,092, filed on Nov. 29, 2000.

(51) Int. Cl. H01L 21/00; H01L 21/84

(52) U.S. Cl. 438/30; 438/151; 438/158

(57) ABSTRACT

An embedded process is provided on the surface of a glass substrate to define an active area and a buried structure. A metal gate and a gate dielectric layer are formed within the buried structure. A drain and a source are formed on the surface of the gate dielectric layer. The drain is electrically connected to a transparent conducting layer while the source is electrically connected to a data line. The final transistor is completed with the deposition of a passivation layer to cover the whole structure.

### BACKGROUND OF THE INVENTION

1.Field of the Invention

The present invention relates to a method of fabricating a transistor of a liquid crystal display (LCD) system, and more particularly, to a method of fabricating a buried transistor.

2.Description of the Prior Art

A thin film transistor liquid crystal display (TFT-LCD) utilizes thin film transistors arranged in a matrix to switch appropriate electrical elements such as capacitors and pads. The electrical elements subsequently drive liquid crystal pixels in the production of brilliant images. The conventional TFT-LCD element comprises of a transparent substrate over which thin film transistors, pixel electrodes, orthogonal scan lines and data lines are positioned. A color filter substrate and liquid materials fill the space between the transparent substrate and the color filter substrate. The TFT-LCD is characterized by its portability, low power consumption and low radiation emission; thus, it is widely used in various portable information products such as notebooks, personal data assistants (PDA), etc. Moreover, TFT-LCDs are increasingly replacing the CRT monitors in desktop computers.

Please refer to FIG. 1 to FIG. 4. FIG. 1 to FIG. 4 are schematic diagrams of a method of fabricating a LCD transistor 10 according to the prior art. As shown in FIG. 1, LCDs are formed on a glass substrate 12. A chromium (Cr) layer (not shown) is formed on the glass substrate 12 and a photo-etching-process (PEP) is performed to form a metal gate 14 on the surface of the glass substrate 12.

As shown in FIG. 2, a chemical vapor deposition (CVD) process is performed to uniformly form a gate dielectric layer 16 of silicon nitride on the glass substrate 12. The thickness of the gate dielectric layer 16 is approximately 4000 angstroms. An amorphous silicon (α-Si) layer 18 and a doped amorphous silicon layer 20 are formed respectively on the surface of the gate dielectric layer 16. A PEP is then performed to pattern the doped amorphous silicon layer 20, the amorphous silicon layer 18 and the gate dielectric layer 16 to create an active area 21. A transparent indium-tin-oxide (ITO) layer 22 is formed on the glass substrate 12 outside of the active area 21. A PEP is again performed to define a first channel 23 located between the metal gate 14 and the ITO layer 22.

As shown in FIG. 3, a CVD process is performed to deposit both a first metal layer 24 of chromium and a second metal layer 26 of aluminum (Al) on the surface of the transistor 10, respectively. A PEP is performed to simultaneously pattern both the metal layers 24,26 as well as to form a second channel 27 atop the surface of the amorphous silicon layer 18. Within the active area 21, the second metal layer 26, the first metal layer 24 and the doped amorphous layer 20 are divided into two regions; one as a source 26a and the second as a drain 26b. As shown in FIG. 4, a silicon nitride layer is uniformly formed on the glass substrate 12 as a passivation layer 28 to thereby finish off the fabrication of the transistor 10.

The prior transistor fabrication process usually utilizes a better conductivity metal to form the first and the second metal layers; the result is the reduction in the resistance in both the metal gate as well as in the scan line. The effect avoids a RC delay effect which can lead to the appearance of ghost images. However, such a two-layer structure inevitably increases the metal layer thickness. As a result, a large drop occurs between the surface of the transistor 10 and the surface of the ITO layer 22 which can make subsequent liquid crystal filling very difficult.

### SUMMARY OF THE INVENTION

It is therefore an objective of the present invention to provide a method of fabricating a buried LCD transistor that not only reduces the resistance of the transistor but also retains a smooth surface structure throughout the whole transistor.

In a preferred embodiment, the present invention first defines an active area on the surface of a glass substrate. An embedding process is performed to form a damascene structure. A metal gate is then formed in the damascene structure. Next, a gate dielectric layer is deposited over the surfaces of the damascene structure and the metal gate. A semiconductor material layer is formed to cover the gate dielectric layer. A planarization process is then performed to remove both the gate dielectric layer and the semiconductor material layer outside of the active layer. The resulting effect is the alignment of the surface of the semiconductor material layer with the surface of the glass substrate. A photoresist layer is then formed on the semiconductor material layer followed by the definition of a channel length of the buried LCD transistor within the photoresist layer. Finally, an ion implantation process is performed to implant the semiconductor material layer not covered by the photoresist layer. Thus, a drain and a source are formed to complete the transistor.

The advantages of the present invention are the embedding of the LCD transistor in the glass substrate and the aligning of the top of the transistor with the surface of the glass transistor. As well, the LCD transistor is a buried transistor. Such advantages prevent drops on the surface of the transistor structure as well as achieving a uniform gap for the whole LCD system for the filling of the liquid crystal.

Another advantage of the present invention is the ability of the metal gate embedded in the glass substrate to receive sufficient space for increasing its thickness. Consequently, an improvement in the production yield occurs through a reduction in the resistance of the metal gate.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 4 are schematic diagrams of a prior art method of fabricating a transistor of a LCD system.

FIG. 5 to FIG. 13 are schematic diagrams of a better embodiment of the present invention for fabricating a LCD transistor.

FIG. 14 and FIG. 15 are schematic diagrams of a second embodiment of the present invention.

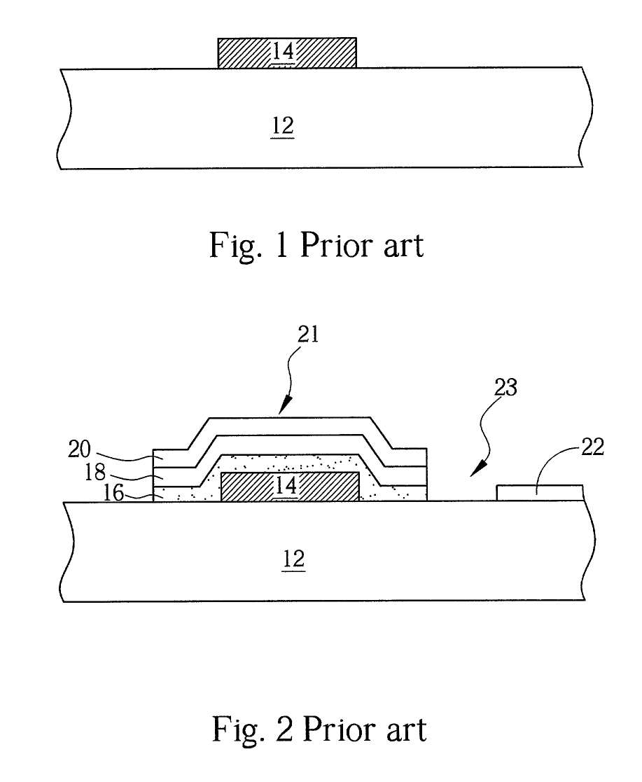

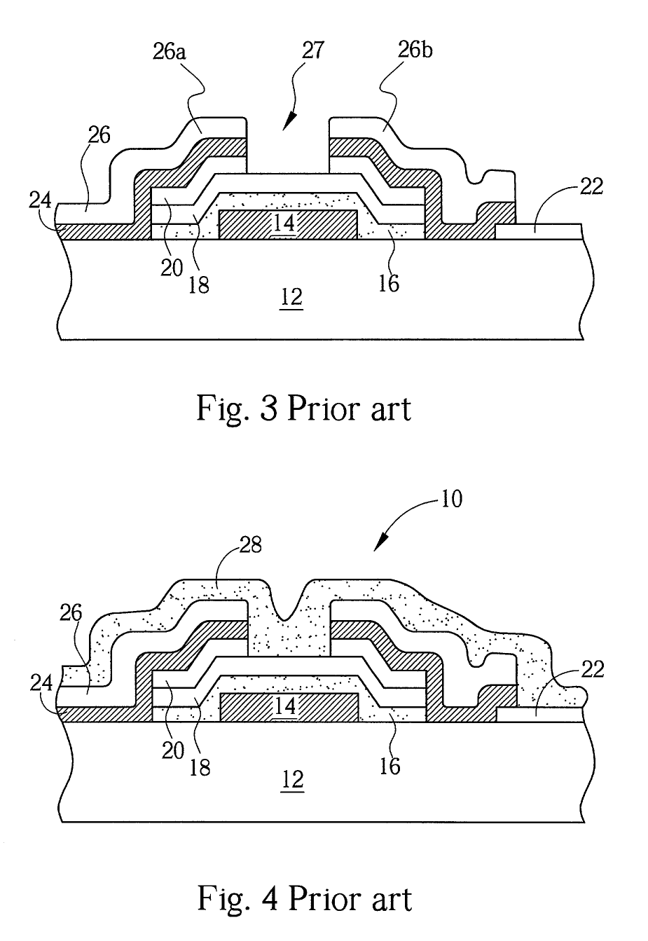

### DETAILED DESCRIPTION OF THE PREFERRED EMBODIMENT

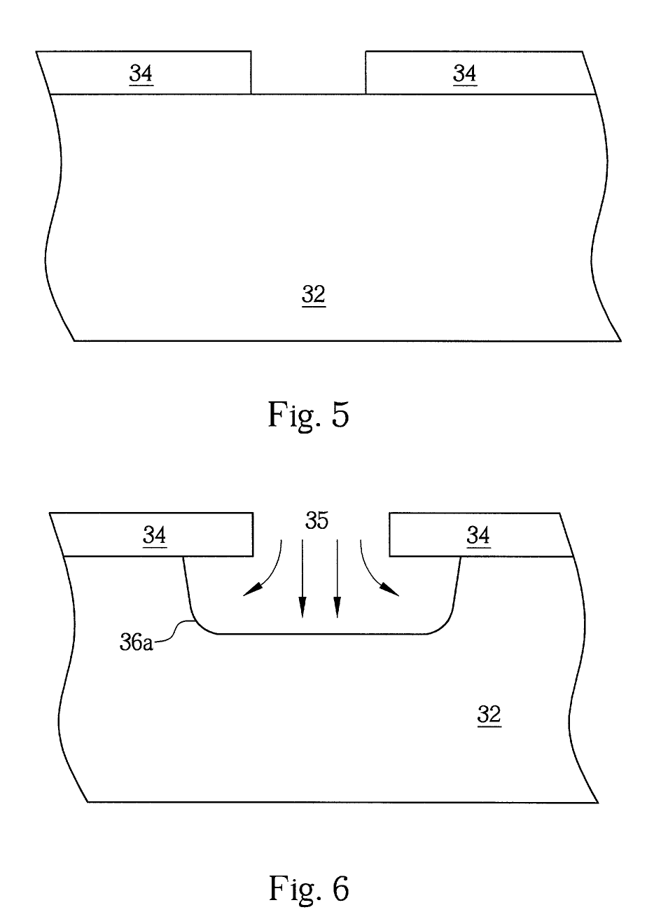

Please refer to FIG. 5 to FIG. 13. FIG. 5 to FIG. 13 are schematic diagrams of a better embodiment of the present invention for fabricating a LCD transistor 30. The LCD transistor 30 of the present invention is primarily used in a twist-nematic (TN) type LCD system. As shown in FIG. 5, a glass substrate 32 of a highly-purified SiO₂ is used. A photoresist layer 34 is formed on the glass substrate 32 to define the position of a damascene structure.

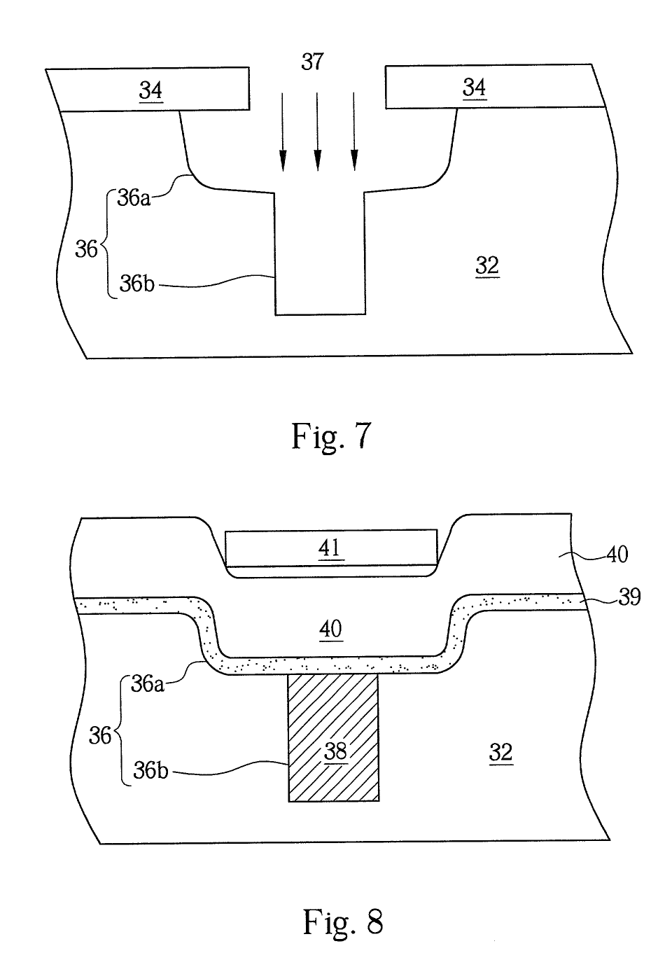

As shown in FIG. 6, a dual damascene process is performed. An anisotropic wet etching process 35, utilizing the photoresist layer 34 as a mask, is first performed on the surface of the glass substrate 32. Hydrofluoric acid (HF), for example, is used as an etching solution to form a first recess 36a. As shown in FIG. 7, a plasma dry etching process 37, again utilizing the photoresist layer 34 as a mask, is performed to etch downward from the bottom of the recess 36a to create a second recess 36b within the glass substrate 32. The length of the vertical cross-section is approximately 30 to 40 micrometers while the width of the horizontal cross-section is approximately 3 to 4 micrometers as determined by the second recess 36b. A recessed damascene structure 36, composed of the first recess 36a and the second recess 36b, is used as a prime structure of the transistor 30.

As shown in FIG. 8, after the removal of the photoresist 34, a CVD process is performed on the surface of the glass substrate 32 to form a metal layer (not shown). The metal layer, comprising of aluminum, chromium, tungsten or an alloy of the aforementioned metals, fills in the second recess 36b. An etching back process is performed to remove the metal layer outside of the second recess 36b to produce a metal gate 38. A gate dielectric layer 39 of silicon nitride is uniformly deposited on the surface of the glass substrate 32 to fill the first recess 36a. Then, a semiconductor layer 40 of polysilicon or amorphous silicon is deposited above the gate dielectric layer 39.

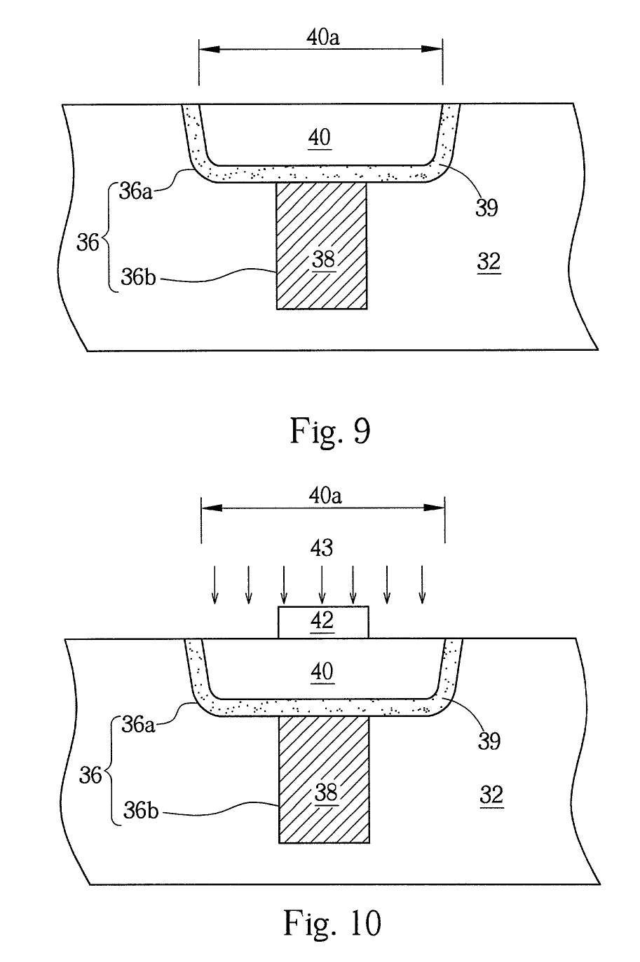

An etching back process is performed to planarize the surface of the transistor 30: Firstly, a photoresist layer 41 is formed atop the portion of the semiconductor layer 40 above the first recess 36a. Then, the photoresist layer 41 is used as a mask to remove the excess semiconductor layer 40. As shown in FIG. 9, a wet etching or a dry etching process is performed to remove the portion of the gate dielectric layer 39 outside the first recess 36a following the stripping of the photoresist layer 41. The surface of the semiconductor layer 40 is approximately aligned with the surface of the glass substrate 32 resulting in a smooth surface throughout the whole transistor 30. Consequently, an active area 40a is formed in the process.

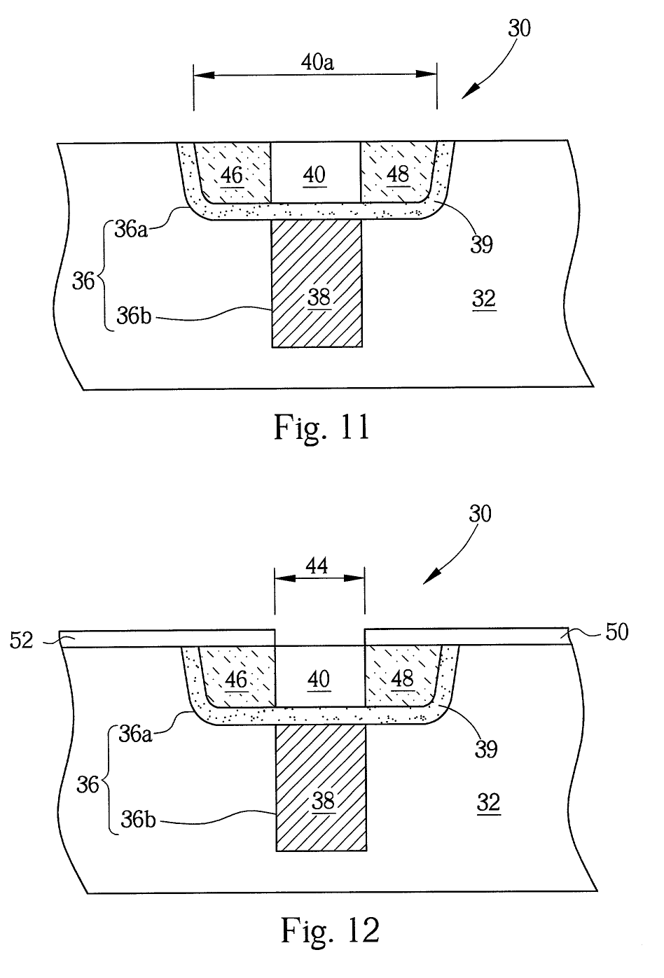

As shown in FIG. 10, a photoresist layer 42 is formed on the surface of the glass substrate 32. Next, an ion implantation process 43 is performed to implant the active area 40a not protected by the photoresist layer 42. As shown in FIG. 11, a source 46 and a drain 48 of the transistor 30 are formed in the active area 40a.

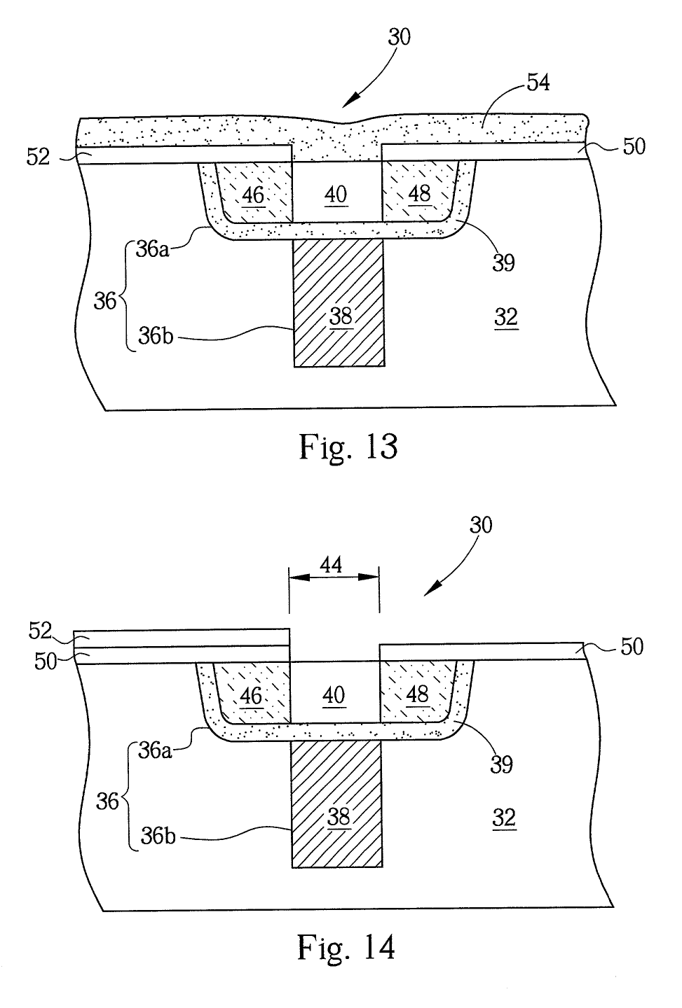

As shown in FIG. 12, a channel 44 is defined on the glass substrate 32 between the source 46 and the drain 48. An ITO layer 50 is formed on the surface of the glass substrate 32 at one side of the channel 44 and electrically connects to the drain 48. A data line 52 is subsequently formed on the surface of the glass substrate 32 at the opposite side of the channel 44 and electrically connects to the source 46. As shown in FIG. 13, a silicon nitride layer, acting as a passivation layer 54, is deposited to uniformly cover the transistor 30 to complete the buried transistor 30.

An etching back process is performed according to the present invention to planarize the surface of the transistor 30 such that the transistor 30 becomes totally buried in the glass substrate 32. The top surface of this inverted transistor 30 is approximately aligned with the surface of the glass substrate 32. Both a transparent ITO layer 50 for forming a pixel electrode and a data line 52 for transporting data to the drain 46 are formed on the glass substrate 32, respectively. Hence, drops on the surface of the TFT-LCD system can be avoided, and a uniform gap can be obtained for the filling of liquid crystal. In addition, the metal gate 38 receives sufficient space to increase its thickness as a result of the increasing depth of the recessed damascene structure 36. Thus, resistance of the metal gate 38 can be reduced and both the RC delay effect and the appearance of ghost images can be prevented to lead to the overall improvement in the performance of the TFT-LCD system.

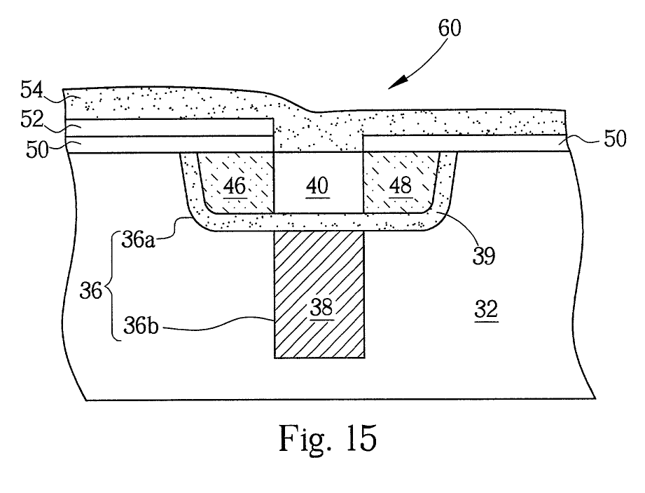

Please refer to FIG. 14 and FIG. 15. FIG. 14 and FIG. 15 are schematic diagrams of a second embodiment of the present invention. As shown in FIG. 14, a channel 44 on the surface of the glass substrate 32 is defined after the formation of the source 46 and the drain 48, (as shown in FIG. 11). A CVD process is then performed to deposit an ITO layer 50 on the complete surface of the glass substrate 32. An etching back process is performed to remove the ITO layer above the channel 44. A polysilicon layer is formed as a data line 52 on the surface of the ITO layer above the drain 46. As shown in FIG. 15, a passivation layer 54 of silicon nitride is deposited on the complete surface of a transistor 60; the fabrication of the buried transistor 60 is thus finished while simultaneously improving transparency of this system.

In contrast to the prior art, the method of fabricating a buried LCD transistor according to the present invention produces a smoother surface in the transistor structure. The effect is the production of a more uniform gap to facilitate liquid crystal filling. In addition, the metal gate buried in the glass substrate receives sufficient space for its increasing thickness and hence reduces its resistance. Both the RC delay effect as well as the appearance of ghost images are obviously prevented, which improves both the performance and the production yield of the TFT-LCD system.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a buried transistor for a liquid crystal display system, the method comprising:
providing a glass substrate;
performing a damascene process on the glass substrate to form a damascene structure therein and to define an active area on the surface of the glass substrate;
forming a metal gate at a bottom portion of the damascene structure;
sequentially depositing a gate insulation layer that covers the interior of the damascene structure and the metal gate, and a semiconductor material layer on the gate insulation layer;
performing a planarization process to remove the semiconductor material layer and the gate insulation layer outside of the active area to make the semiconductor material layer approximately flush with the surface of the glass substrate;
forming a photoresist layer on the semiconductor material layer, the photoresist layer defining the channel length of the buried transistor; and
performing an ion implantation process to dope the semiconductor material layer that is not covered by the photoresist layer to form a source and a drain of the buried transistor.

2. The method of claim 1 wherein the formation of the metal gate comprises the following steps:
depositing a metal layer on the glass substrate and filling the damascene structure with the metal layer; and
performing an etch-back process to etch a pre-selected depth of the metal layer in the damascene structure and to remove the metal layer outside of the damascene structure.

3. The method of claim 2 wherein the vertical dimension of a vertical cross-section of the metal gate is between 30 to 40 micrometers, and the horizontal dimension of the cross-section of the metal gate is between 3 to 4 micrometers.

4. The method of claim 2 wherein the metal gate is made from aluminum, chromium, copper, tungsten, or alloys of the aforementioned metals.

5. The method of claim 1 wherein the damascene process comprises a wet etching process that is used to define the active area in the glass substrate, and a plasma etching process that is used to define a metal gate recess within the active area.

6. The method of claim 1 wherein the damascene process is a dual-damascene process.

7. The method of claim 1 wherein the semiconductor material layer is composed of polysilicon or amorphous silicon.

8. The method of claim 1 wherein the gate insulation layer is composed of silicon nitride.
